(19) United States
(12) Patent Application Publication
(10) Pub. No.: US 2026/0118777 A1
(43) Pub. Date: Apr. 30, 2026

(54) NON-CONTACT TEMPERATURE SENSOR FOR A MIRROR, PROJECTION LENS AND METHOD FOR MEASURING THE TEMPERATURE OF A MIRROR

(71) Applicant: Carl Zeiss SMT GmbH, Oberkochen (DE)

(72) Inventors: Martin BICKERT, Vallendar (DE); Thomas MONZ, Schlierbach (DE)

(21) Appl. No.: 19/395,659

(22) Filed: Nov. 20, 2025

Related U.S. Application Data
(63) Continuation of application No. PCT/EP2024/064352, filed on May 24, 2024.

(30) Foreign Application Priority Data
May 31, 2023 (DE) 10 2023 205 090.0

(51) Int. Cl. G03F 7/00; G01J 5/0806; G01J 5/0818

(52) U.S. Cl. CPC G03F 7/70891; G01J 5/0806; G01J 5/0818; G03F 7/70241; G03F 7/70316; G03F 7/7085

(57) ABSTRACT

A mirror device for a microlithographic projection exposure apparatus has at least one mirror. The mirror comprises a mirror body and a reflection surface formed on the mirror body. At least one depression is present and extends from a back side of the mirror body distant from the reflection surface through the mirror body in the direction of the reflection surface. The depression has, at the end facing the reflection surface, a measurement area thermally connected to the reflection surface and a sensor unit. The sensor unit is formed as an infrared temperature sensor and configured for contactless determination of the temperature of the measurement area vis-à-vis the measurement area.

### CROSS-REFERENCE TO RELATED APPLICATIONS

The present application is a continuation of, and claims benefit under 35 USC 120 to, international application No. PCT/EP2024/064352, filed May 24, 2024, which claims benefit under 35 USC 119 of German Application No. 10 2023 205 090.0, filed May 31, 2023. The entire disclosure of each of these applications is incorporated by reference herein.

### FIELD

The disclosure relates to a mirror device for a microlithographic projection exposure apparatus, having at least one mirror, wherein the mirror comprises a mirror body and a reflection surface formed on the mirror body, wherein at least one depression is present and extends from a back side of the mirror body distant from the reflection surface through the mirror body in the direction of the reflection surface, wherein the depression has, at the end facing the reflection surface, a measurement area thermally connected to the reflection surface, and having a sensor unit. The disclosure also relates to a projection lens and a method for measuring the temperature of a mirror.

### BACKGROUND

Projection exposure apparatuses are used to produce extremely fine structures, for example on semiconductor components or other microstructured component parts. The operating principle of the apparatuses is based on the production of extremely fine structures down to the order of nanometres by way of generally reducing imaging of structures on a mask, a so-called reticle, on an element to be structured, a so-called wafer, that is provided with photosensitive material. The minimum dimensions of the structures produced are, in general, directly dependent on the wavelength of the light used. The light is shaped for the optimum illumination of the reticle in an illumination optics unit. Recently, light sources having an emission wavelength in the order of a few nanometres, for example between 1 nm and 120 nm, for example on the order of 13.5 nm, have increasingly been used. The described wavelength range is also referred to as the EUV range.

Apart from with the use of systems which operate in the EUV range, the microstructured component parts are also produced using commercially established DUV systems, which have a wavelength of between 100 nm and 300 nm, for example 193 nm. With the general desire to be able to produce smaller and smaller structures, the desired optical correction in the systems has likewise increased further. In general, throughput is increased to increase efficiency with each new generation of projection exposure apparatuses in the EUV range or DUV range.

The projection exposure apparatus can comprise multiple mirrors off which the radiation is reflected. The mirrors can have a precisely defined shape and are precisely positioned in order that the imaging of the mask onto the lithography object is of sufficient quality. During operation, the projection exposure apparatus is subjected to influences which have an influence on the imaging quality. For example, if a thermal expansion leads to a change in the geometric shape of a mirror, then the wavefront of the radiation reflected off the mirror changes. Optimal use of the mirrors thus involves accurate knowledge about the temperature at the active mirror surface, i.e. the region of the reflection surface impinged upon by the electromagnetic radiation. To this end, it is usual practice to drill bores into the mirror body on the back side of the mirror body, and temperature sensors are then accommodated in the bores. The temperature sensors are usually based on electrical effects and adhesively bonded into the bore. Where possible, electrically conductive cables are used to read the temperature sensors; however, these cables can lead to mechanical coupling between the mirror body and the surroundings. This may lead to disturbances in the mirror performance, for which reason very thin and hence very sensitive cables are usually used. This in turn can increase the demands on the manufacture and operation of the mirror device. The temperature information may be used in turn, for example, to control a heating module or a cooling module, such that the temperature of the entire mirror is kept at a constant value, or to suitably adjust the projection exposure apparatus after a temperature change.

### SUMMARY

The present disclosure seeks to allow more accurate temperature measurement on the active mirror surface and to reduce certain undesired properties.

The disclosure relates to a mirror device for a microlithographic projection exposure apparatus. The mirror device has at least one mirror which comprises a mirror body and a reflection surface formed on the mirror body. At least one depression is present and extends from a back side of the mirror body distant from the reflection surface through the mirror body in the direction of the reflection surface. The depression has, at the end facing the reflection surface, a measurement area thermally connected to the reflection surface and a sensor unit. The sensor unit is formed as an infrared temperature sensor and configured for non-contact determination of the temperature of the measurement area vis-à-vis the measurement area.

The sensor unit is formed as an infrared temperature sensor and configured for non-contact determination of the temperature of the measurement area vis-à-vis the measurement area. The temperature of the reflection surface may be determined in certain areas by using a contactless detection of the infrared radiation emitted by the measurement area to measure the temperature of the measurement area thermally connected to the reflection surface. The contactless detection of the measurement signal, i.e. the infrared radiation emitted by the measurement area, can allow the temperature of the measurement area and hence the temperature of the reflection surface or active mirror surface to be detected, wherein the interventions in the mirror device and its configuration may be as small as reasonably possible. In this context, a contactless detection vis-à-vis the measurement area is understood to mean that at least the measurement area and the temperature sensor are mechanically decoupled from each other, i.e. there is a non-contact temperature measurement vis-à-vis the measurement area. In other words, from a mechanical point of view, the temperature sensor is completely or at least partially decoupled from the mirror, with no direct mechanical connection being present between the temperature sensor and the measurement area. The infrared temperature sensor can be sensitive to long-wavelength IR radiation having wavelengths of between 7 μm and 14 μm. In this context, the measurement area may correspond to the entire base of the depression, with it being optional for the measurement area to correspond to only a portion of the base. For example, the size of the measurement area may be between 1 μm² and 1 mm². For example, the measurement area may be smaller than 5 mm², such as smaller than 2 mm², for example smaller than 1 mm².

Furthermore, the depression can extend through the mirror body nearly up to the reflection surface. Moreover, the depression may also have a stepped embodiment, i.e. have different diameters along its longitudinal extent. The closer the measurement area is arranged to the reflection surface, the more accurately the temperature of the reflection surface may be inferred by way of measuring the temperature of the measurement area. In this case, the depression can be formed as a bore.

The reflection surface of the mirror may be designed for a high reflectivity of EUV radiation and/or DUV radiation. The term EUV radiation denotes electromagnetic radiation in the extreme ultraviolet spectral range with wavelengths of between 5 nm and 100 nm, for example with wavelengths of between 5 nm and 30 nm. DUV radiation is in the deep ultraviolet spectral range and has a wavelength of between 100 nm and 300 nm. The reflection surface may be formed by a highly reflective coating. This may be a multilayer coating, for example a multilayer coating having alternating layers of molybdenum and silicon. Using such a coating, it is possible to reflect approximately 70% of the incident EUV radiation. The approximately 30% that remains is absorbed and can lead to heating of the EUV mirrors.

Furthermore, it is possible for the sensor unit to be arranged such that there is a non-contact temperature measurement vis-à-vis the mirror body, i.e. there is complete decoupling between the sensor unit and the mirror body. To this end, the mirror body may be mounted on a frame in an embodiment, wherein the mount may be movable such that the position of the mirror body is adjustable relative to the frame. In this context, the sensor unit can be arranged on or secured to the frame. In an alternative, the mirror body may be borne on a bearing in this context, with the sensor unit being secured to the bearing. This again can allow the sensor unit to be decoupled from the mirror body and thus can help enable a more accurate temperature measurement and a disturbance-reduced and hence improved operation of the mirror device.

In a further alternative embodiment, however, the sensor unit may be also secured to the mirror body itself. In this case, provision may be made for example for the sensor unit to be secured to a securing mechanism that is connected or connectable to the mirror body. This can help reduce the distance between the sensor unit and also the mirror body and a frame.

Moreover, the sensor unit can comprise an optical system, an infrared detector and electronics assigned to the infrared detector, wherein the optical system is arranged in the beam path between the measurement area and the infrared detector. The optical system can be used to image the measurement signal, i.e. the infrared radiation emitted by the measurement area, from the measurement area onto the infrared detector. Using electronics, the infrared detector can convert the IR measurement signal into an electrical signal which is transmitted in analogue or digital fashion via an external interface to a control unit for display or further processing purposes. Furthermore, it is possible for the optical system to comprise at least a lens element, for example a converging lens element, wherein the optical system may also comprise multiple lens elements/converging lens elements or, in an alternative, a stop as well. The sensor unit can comprise a housing, with which the sensor unit is secured to the frame or the mount or the mirror body. The infrared sensor unit may be in the form of an image sensor, such that the infrared radiation emitted by the mirror body may be detected in a spatially resolved manner. The infrared detector may take the form of a bolometer, of thermopiles or of semiconductor sensors (e.g. InSb, HgCdTE).

In an embodiment with a relatively simple design, the sensor unit may also comprise only an infrared detector and electronics, i.e. be formed without an additional optical system.

At least part of the sensor unit can be accommodated in the depression, wherein at least 50% of the longitudinal extent of the sensor unit, such as 75%, for example 80%, of the longitudinal extent of the sensor unit is accommodated in the depression. Thus, the depression can be designed to be accessible from the outside on the back side of the mirror body distant from the reflection surface, with the result that the sensor unit may be at least partially inserted into the depression from there. The diameter of the sensor unit can consequently be less than the diameter of the depression.

In order to be able to determine the temperature as accurately as reasonably possible and to be able to keep the distance between the measurement area and the optical system as small as reasonably possible, the optical system can be in the form of a light guide, at least certain areas of which are accommodated in the depression or which extends through the depression in the direction of the measurement area. The light guide can guide the infrared measurement signal from the measurement area to the infrared detector. In this case, the infrared detector and the electronics assigned to the infrared detector can be secured to the frame or to a bearing, while one end of the light guide is connected to the detector and projects into the depression or else extends through the depression. This can help allow the sensor unit to be decoupled from the mirror body and the distance between the measurement area and the sensor unit is simultaneously chosen to be so small that an infrared background radiation, for example from a frame of the mirror device or an adjacent housing, is suppressed.

In an alternative embodiment, the sensor unit can be arranged outside of the depression and for a deflection mirror to be additionally arranged outside of the depression, in such a way that the measurement signal from the measurement area is deflected onto the optical system and/or the infrared detector. This also can help allow the sensor unit to be decoupled from the mirror body such that the mechanical properties of the mirror, for instance its natural frequency and for example the control bandwidth of the position control and/or the maximum travel, are not influenced or only influenced to a small extent. The deflection mirror and the optical system, i.e. the at least one lens element, and the infrared detector and the electronics can be secured to the frame or to a bearing.

To help increase the measurement signal, it is possible for a target to be formed on the measurement area and to have a higher emissivity for infrared radiation vis-à-vis an inner wall of the depression or a region of the depression without the measurement area.

In order to be able to determine the temperature of the reflection surface of the entire active mirror surface region, a plurality of depressions that are arranged at a distance from one another and extend from the back side of the mirror body in the direction of the reflection surface can be present and for each of the depressions to be assigned a sensor unit in the form of an infrared temperature sensor or to be arranged therein. The depressions may be arranged relative to one another as desired. For example, the depressions may be arranged at regular distances from one another. Alternatively, a first region of the reflection surface may have a greater number of depressions than a second region of equal size.

The disclosure also relates to a projection exposure lens for a microlithographic projection exposure apparatus, wherein a mask is imaged onto a lithography object by way of a plurality of mirror devices, wherein at least one of the mirror devices is in the form of a mirror device according to the disclosure.

The features and embodiments of the mirror device may in this case be applied to the projection lens comprising the mirror device.

The disclosure may also be used in an illumination module for a microlithographic projection exposure apparatus having a light source, wherein at least one mirror device is in the form of a mirror device according to the disclosure.

The features and embodiments of the mirror device may in this case be applied to the illumination module comprising the mirror device.

The disclosure also relates to a method for measuring the temperature of a mirror in a microlithographic projection exposure apparatus, wherein the mirror comprises a mirror body and a reflection surface formed on the mirror body, a depression that extends from the back side of the mirror body in the direction of the reflection surface being formed in the mirror body and a measurement area being arranged at the end of the depression facing the reflection surface, an infrared measurement signal is acquired at the measurement area without contact using an infrared temperature sensor, and a temperature value of the measurement area is derived from the infrared measurement signal. The temperature value can be transferred to a control unit. The temperature measurement value may be processed further by the control unit, for example by virtue of a temperature control element being controlled on the basis of the measured temperature value in order to keep the temperature of the mirror constant.

Moreover, the disclosure may also be used in the case of optical elements other than mirrors, for example in the case of lens elements.

Further features, properties and aspects of the present disclosure are described in more detail below on the basis of embodiment variants and with reference to the appended figures. In this respect, all the features described above and below are can be combined both individually and in any desired combination. The embodiment variants described below are merely examples which, however, do not limit the subject matter of the disclosure.

### BRIEF DESCRIPTION OF THE DRAWINGS

In the figures:

FIG. 1A shows a schematic illustration of a microlithographic projection exposure apparatus designed for operation in the EUV;

FIG. 1B shows a schematic illustration of a microlithographic projection exposure apparatus designed for operation in the DUV;

FIG. 2 shows a schematic illustration of a first exemplary embodiment of a mirror device;

FIG. 3 shows a schematic illustration of a second exemplary embodiment of a mirror device;

FIG. 4 shows a schematic illustration of a third exemplary embodiment of a mirror device; and

FIG. 5 shows a schematic illustration of a fourth exemplary embodiment of a mirror device.

### DETAILED DESCRIPTION

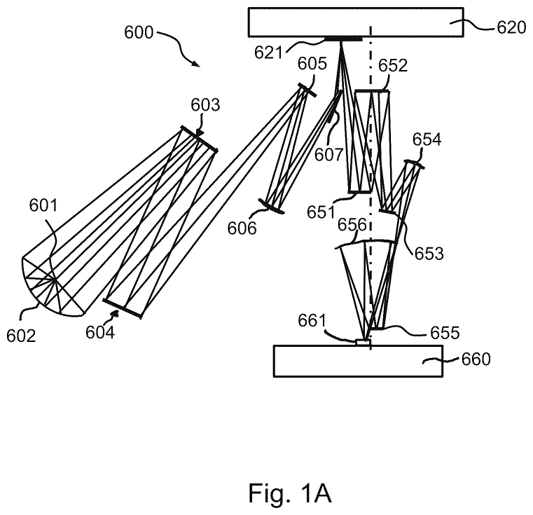

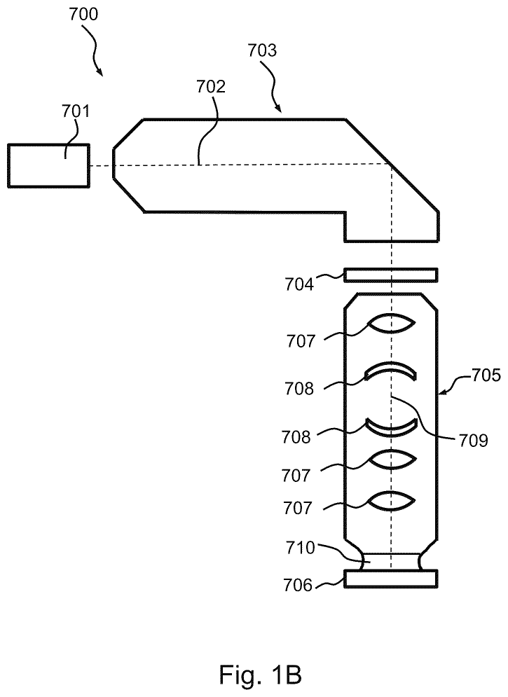

FIG. 1A shows a schematic illustration of an exemplary projection exposure apparatus 600 which is designed for operation in the EUV and in which the present disclosure can be realized.

According to FIG. 1A, an illumination module in a projection exposure apparatus 600 designed for EUV comprises a field facet mirror 603 and a pupil facet mirror 604. The light from a light source unit comprising a plasma light source 601 and a collector mirror 602 is directed to the field facet mirror 603. A first telescope mirror 605 and a second telescope mirror 606 are arranged downstream of the pupil facet mirror 604 in the light path. A deflection mirror 607 is arranged downstream in the light path and directs the radiation that is incident thereon onto an object field in the object plane of a projection lens comprising six mirrors 651-656. At the location of the object field, a reflective structure-bearing mask 621 is arranged on a mask stage 620 and with the aid of the projection lens is imaged into an image plane, in which a substrate 661 coated with a light-sensitive layer (photoresist) is situated on a wafer stage 660.

The disclosure may likewise be used in a DUV apparatus, as illustrated in FIG. 1B. A DUV apparatus is set up in principle like the above-described EUV apparatus from FIG. 1A, wherein mirrors and lens elements can be used as optical elements in a DUV apparatus, and the light source of a DUV apparatus emits used radiation in a wavelength range of 100 nm to 300 nm.

The DUV lithography apparatus 700 illustrated in FIG. 1B comprises a DUV light source 701. For example, an ArF excimer laser that emits radiation 702 in the DUV range at for example 193 nm may be provided as the DUV light source 701. A beam shaping and illumination module 703 guides the DUV radiation 702 onto a photomask 704. The photomask 704 is in the form of a transmissive optical element and may be arranged outside the beam shaping and illumination module 703. The photomask 704 comprises a structure that is imaged onto a wafer 706 or the like in a reduced fashion via the projection system 705. The projection system 705 comprises multiple lens elements 707 and/or mirrors 708 for imaging the photomask 704 onto the wafer 706. In this case, individual lens elements 707 and/or mirrors 708 of the projection system 705 may be arranged symmetrically with respect to the optical axis 709 of the projection system 705. It should be noted that the number of lens elements 707 and mirrors 708 of the DUV lithography apparatus 700 is not restricted to the number illustrated. A greater or lesser number of lens elements 707 and/or mirrors 708 may also be provided. For example, the beam shaping and illumination module 703 of the DUV lithography apparatus 700 comprises multiple lens elements 707 and/or mirrors 708. Furthermore, the mirrors are generally curved on their front side for beam shaping purposes. An air gap 710 between the last lens element 707 and the wafer 706 may be replaced by a liquid medium having a refractive index of >1. The liquid medium may be high-purity water, for example. Such a construction is also referred to as immersion lithography and has an increased photolithographic resolution.

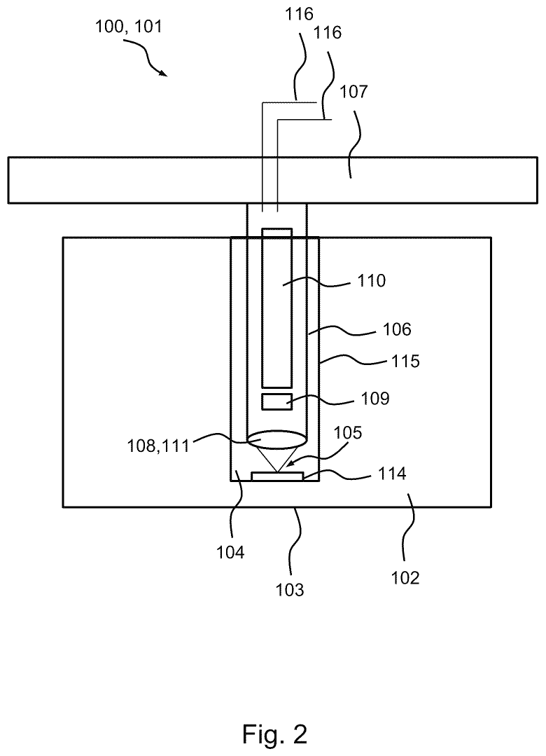

FIG. 2 shows a mirror device 100 for the microlithographic projection exposure apparatus 600, 700, having a mirror 101, wherein the mirror 101 comprises a mirror body 102 and a reflection surface 103 formed on the mirror body 102. Furthermore, a depression 104 is present and extends from a back side of the mirror body 102 distant from the reflection surface 103 through the mirror body 102 in the direction of the reflection surface 103, wherein the depression 104 has, at the end facing the reflection surface 103, a measurement area 105 thermally connected to the reflection surface 103. In the present case, the depression 104 is formed as a bore. A sensor unit 106 in the form of an infrared temperature sensor and configured for non-contact determination of the temperature of the measurement area 105 vis-à-vis the measurement area 105 is present for the purpose of determining the temperature of the mirror body 102 or the active surface of the mirror 101. In this case, the mirror 101 of the mirror device 100 may be in the form of a mirror of the projection lens or in the form of a mirror of the illumination module of the microlithographic projection exposure apparatus 600, 700.

In order to be able to perform a temperature measurement that is as accurate as reasonably possible and keep the influence of the sensor unit and the measurement procedure on the mirror 101 as small as reasonably possible, the sensor unit 106 is arranged in a manner decoupled from the mirror body 102. In the present case, the sensor unit 106 is attached to a frame 107, with the mirror body 102 optionally being mounted on the frame 107 in movable fashion. In an alternative—and not shown in the present case—the mirror body 102 may also be borne on a bearing in the case of a frameless mirror 101, with the sensor unit 106 being arranged on the bearing. The sensor unit 106 comprises an optical system 108, an infrared detector 109 and electronics 110 assigned to the infrared detector, wherein the optical system 108 is arranged between the measurement area 105 and the infrared detector 109. In the present case, the optical system 108 is formed as at least one lens element 111. The optical system 108 is used to image the measurement signal emitted by the measurement area 105, i.e. the infrared radiation, onto the infrared detector 109. The optical signal is converted into an electronic signal via the electronics 110 of the infrared detector and may be transmitted in digital or analogue fashion to a control unit or display (not depicted in detail) by way of an external interface 116.

The temperature of the measurement area 105 ascertained thus may be processed further via the control unit. For example, the mirror body 102 may contain a cooling system or temperature control system (not depicted in detail) that takes up appropriate heating or cooling measures in order to keep the temperature of the mirror 101 constant should the measured temperature deviate from a predetermined or predeterminable temperature. To amplify the measurement signal, a target 114 is formed on the measurement area 105 and has a higher emissivity for infrared radiation vis-à-vis the inner wall 115 of the depression 104 or the region of the depression 104 without the measurement area.

In order to be able to perform a temperature measurement that is as accurate as reasonably possible, at least a part and optionally a majority of the sensor unit 106 is accommodated in the depression 104. This enables an accurate temperature measurement since the measurement is performed very close to the measurement area 105, and so background effects such as the infrared background radiation of the frame 107 are negligible. Moreover, there are no mechanical transfers from the sensor unit 106 to the mirror body, or these are reduced, as a result of the sensor unit 106 being decoupled from the mirror body 102.

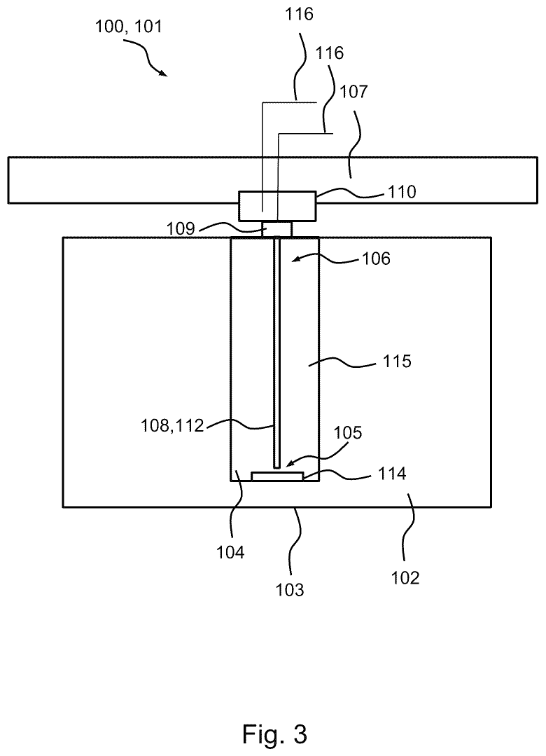

FIG. 3 shows a further example of a sensor unit 106 that is decoupled from the mirror body 102 and performs a non-contact measurement vis-à-vis the mirror body 102 and the measurement area 105. In this case, the optical system 108 of the sensor unit 106 is formed as a light guide 112, at least certain areas of which are accommodated in the depression 104 or which extends through the depression 104 in the direction of the measurement area 105. The light guide 112 is arranged in a protective housing (not depicted in detail) and connected to the infrared detector 109 at one end.

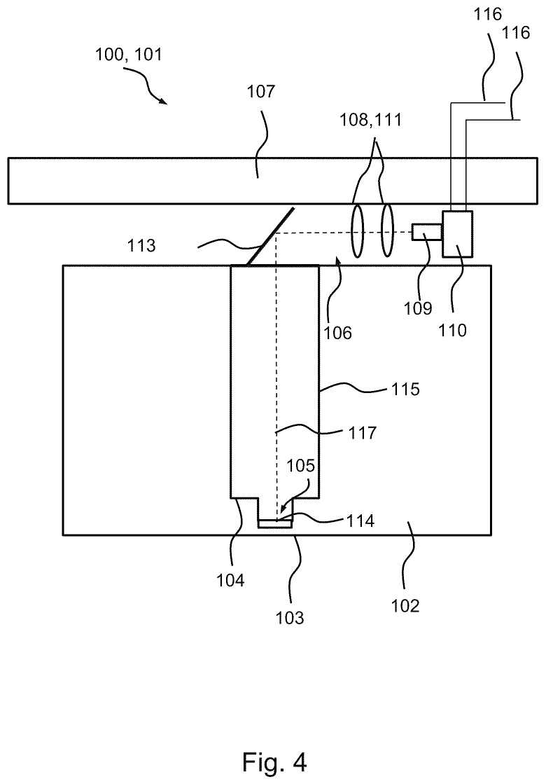

FIG. 4 shows a further exemplary embodiment of a mirror device 100, with the latter differing in that the sensor unit 106 is arranged outside of the depression 104 and in that a deflection mirror 113 is additionally arranged outside of the depression 104, in such a way that the measurement signal 117 from the measurement area 105 is deflected onto the optical system 108 and/or the infrared detector 109. In the present case, the sensor unit 106 is also arranged on or attached to the frame 107 or a bearing (not depicted in detail) such that the sensor unit 106 is mechanically decoupled from the mirror body 102. However, in an alternative embodiment, it is also possible for the sensor unit 106 to be borne on the mirror body 102.

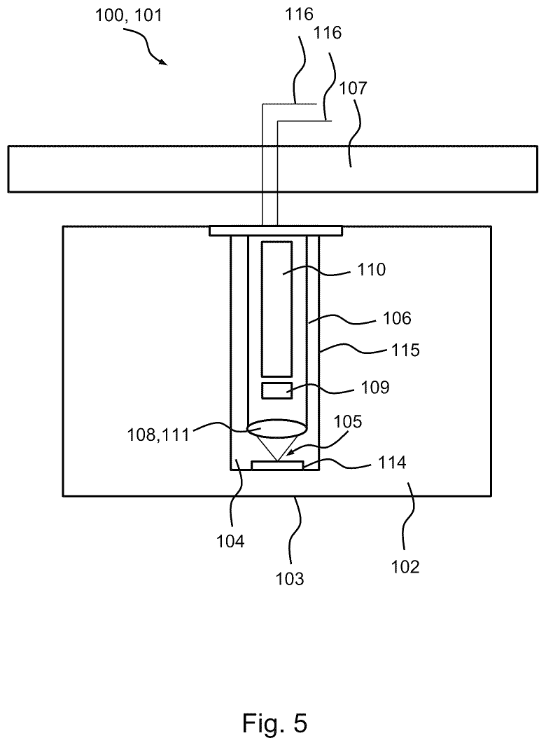

FIG. 5 shows a further exemplary embodiment of a mirror device 100, with the latter differing in that although the sensor unit 106 acquires the measurement signal vis-à-vis the measurement area 105 without contact, the sensor unit 106 is secured to the mirror body 102. The sensor unit 106 is fully accommodated in the depression 104 and attached to the back side of the mirror body 102 via a fastening mechanism 118.

In order to be able to determine the temperature of a relatively large region of the active mirror surface, all exemplary embodiments shown in FIGS. 2 to 5 may also comprise a plurality of depressions 104 that are arranged at a distance from one another and extend from the back side of the mirror body 102 in the direction of the reflection surface 103. A sensor unit 106 in the form of an infrared temperature sensor is assigned to or arranged in each depression 104.

### LIST OF REFERENCE SIGNS

100 Mirror device
101 Mirror
102 Mirror body
103 Reflection surface
104 Depression
105 Measurement area
106 Sensor unit (infrared temperature sensor)
107 Frame
108 Optical system
109 Infrared detector
110 Electronics
111 Lens element
112 Light guide
113 Deflection mirror
114 Target
115 Inner wall (depression)
116 External interface
117 Measurement signal
600 Projection exposure apparatus
601 Plasma light source
602 Collector mirror
603 Field facet mirror (illumination module)
604 Pupil facet mirror (illumination module)
605 First telescope mirror (illumination module)
606 Second telescope mirror (illumination module)
607 Deflection mirror (illumination module)
620 Mask stage
621 Mask
651 Mirror (projection lens)
652 Mirror (projection lens)
653 Mirror (projection lens)
654 Mirror (projection lens)
655 Mirror (projection lens)
656 Mirror (projection lens)
660 Wafer stage
661 Coated substrate
700 DUV lithography apparatus
701 DUV light source
702 DUV radiation/beam path
703 Beam shaping and illumination module (DUV)
704 Photomask
705 Projection system
706 Wafer
707 Lens element
708 Mirror
709 Optical axis

What is claimed is:

1. A mirror device, comprising:
a frame;
a mirror comprising a mirror body and a reflection surface supported by the mirror body; and
an infrared temperature sensor,
wherein:
a depression extends from a back side of the mirror body distant from the reflection surface and into the mirror body toward the reflection surface;
a measurement area is thermally connected to the reflection surface at an end of the depression facing the reflection surface;
the infrared temperature sensor is configured to determine the temperature of the measurement area without contacting the measurement area; and
one of the following holds:
the mirror body is mounted on a frame, and the infrared temperature sensor unit is on the frame; or
the mirror body is borne on a bearing, and the sensor unit is on the bearing.

2. The mirror device of claim 1, wherein the depression is a bore.

3. The mirror device of claim 1, wherein the infrared temperature sensor is decoupled from the mirror body.

4. The mirror device of claim 1, wherein:
the infrared temperature sensor comprises an optical system, an infrared detector and electronics assigned to the infrared detector; and
the optical system is between the measurement area and the infrared detector.

5. The mirror device of claim 4, wherein the optical system comprises a lens element.

6. The mirror device of claim 4, wherein the optical system comprises a light guide.

7. The mirror device of claim 6, wherein at least certain areas of the light guide are in the depression, or wherein the light guide extends through the depression toward the measurement area.

8. The mirror device of claim 4, further comprising a deflection mirror, wherein the infrared temperature sensor is outside the depression, and the deflection mirror is outside the depression so that a measurement signal from the measurement area is deflected onto the optical system and/or the infrared detector.

9. The mirror device of claim 1, wherein the infrared temperature sensor is at least partly accommodated in the depression.

10. The mirror device of claim 1, further comprising a deflection mirror, wherein the infrared temperature sensor is outside the depression, and the deflection mirror is outside the depression so that a measurement signal from the measurement area is deflected onto the infrared detector.

11. The mirror device of claim 1, wherein the measurement area comprises a target having a an emissivity for infrared radiation that is higher than an emissivity for infrared radiation of an inner wall of the depression.

12. The mirror device of claim 1, wherein the measurement area comprises a target having a an emissivity for infrared radiation that is higher than an emissivity for infrared radiation of a region of the depression without a base.

13. The mirror device of claim 1, comprising a plurality of depressions and a plurality of infrared temperature sensors, wherein:
each depression extends from the back side of the mirror body distant from the reflection surface and through the mirror body toward the reflection surface;
each depression is assigned a corresponding one of the infrared temperature sensors.

14. The mirror device of claim 13, wherein, for at least one of the infrared temperature sensors:
the infrared temperature sensor comprises an optical system, an infrared detector and electronics assigned to the infrared detector; and
the optical system is between the measurement area and the infrared temperature sensor.

15. The mirror device of claim 1, wherein the mirror body is mounted on a frame, and the infrared temperature sensor unit is on the frame.

16. The mirror device of claim 1, wherein the mirror body is borne on a bearing, and the sensor unit is on the bearing.

17. A sub system, comprising:
a plurality of mirror device configured to image an object in an object field of the lens into an image field of the lens,
wherein:
at least one of the mirror devices comprises a mirror device according to claim 1; and
the subsystem comprises a projection lens, or the subsystem comprises an illumination optics unit.

18. An apparatus, comprising:
an illumination optics unit; and
a projection lens,
wherein:
the illumination optics unit is configured to illuminate an object in an object field of the projection lens;
the projection lens is configured to image the illuminated object into an image field of the projection lens;
the illumination optics and/or the projection lens comprises a plurality of mirror devices comprising at least one mirror device according to claim 1; and
the apparatus comprises a microlithographic projection exposure apparatus.

19. A method of using a microlithographic projection exposure apparatus comprising an illumination optics unit and a projection lens, the method comprising:
using the illumination optical unit to illuminate an object in an object field of the projection lens; and
using the projection lens to image the illuminated object into an image field of the projection lens,
wherein the illumination optical unit and/or the projection lens comprises a plurality of mirror devices comprising at least one mirror device according to claim 1.

20. A method of measuring a temperature of a mirror in a microlithographic projection exposure apparatus, the mirror comprising a mirror body and a reflection surface supported by the mirror body, a depression extending from a back side of the mirror body distant from the reflection surface and into the mirror body toward the reflection surface, a measurement area that is thermally connected to the reflection surface being at the end of the depression facing the reflection surface, the method comprising:
using an infrared temperature sensor to acquire an infrared measurement signal vis-à-vis the measurement area at the measurement area without the infrared temperature sensor contacting the measurement area; and
deriving a temperature value of the measurement area from an infrared measurement signal from the infrared temperature sensor,
wherein one of the following holds:
the mirror body is mounted on a frame, and the infrared temperature sensor unit is on the frame; or
the mirror body is borne on a bearing, and the sensor unit is on the bearing.
